(19) United States
(12) Patent Application Publication
(10) Pub. No.: US 2026/0215028 A1
(43) Pub. Date: Jul. 23, 2026

(54) TUNNEL OXIDE PASSIVATED CONTACT SOLAR CELL AND PHOTOVOLTAIC MODULE

(71) Applicant: BYD COMPANY LIMITED, Shenzhen (CN)

(72) Inventors: Xue LUO, Shenzhen (CN); Jiaxin ZHENG, Shenzhen (CN); Yan LI, Shenzhen (CN); Canlin OU, Shenzhen (CN); Wei ZHOU, Shenzhen (CN)

(21) Appl. No.: 19/456,478

(22) Filed: Jan. 22, 2026

Related U.S. Application Data
(63) Continuation of application No. PCT/CN2024/106902, filed on Jul. 23, 2024.

(30) Foreign Application Priority Data
Jul. 24, 2023 (CN) 202321961965.8

(51) Int. Cl. H10F 77/30

(52) U.S. Cl. CPC H10F 77/315

(57) ABSTRACT

A tunnel oxide passivated contact solar cell includes a first plurality of sequentially stacked layers, with such sequentially stacked layers including a first anti-reflection layer, a passivation layer, an electrode emission layer, a silicon substrate layer, a tunnel oxide layer, a polycrystalline silicon-doped stack structure layer, and a second anti-reflection layer. The polycrystalline silicon-doped stack structure layer includes a second plurality of sequentially stacked layers, with such sequentially stacked layers including a first phosphorus-doped polycrystalline silicon layer, a phosphorus-carbon co-doped polycrystalline silicon layer, a second phosphorus-doped polycrystalline silicon layer, and a phosphorus-hydrogen co-doped polycrystalline silicon layer. The first phosphorus-doped polycrystalline silicon layer is in contact with the tunnel oxide layer.

### CROSS-REFERENCE TO RELATED APPLICATIONS

This application is a bypass continuation of International Patent Application No. PCT/CN2024/106902, filed on Jul. 23, 2024, which in turn claims priority to Chinese Patent Application No. 202321961965.8, filed with the China National Intellectual Property Administration on Jul. 24, 2023 and entitled “TUNNEL OXIDE PASSIVATED CONTACT SOLAR CELL AND PHOTOVOLTAIC MODULE”, both of which are hereby incorporated herein by reference in their entirety for all purposes.

### TECHNICAL FIELD

This application relates to the field of solar cell technologies, and specifically, to a tunnel oxide passivated contact solar cell and a photovoltaic module.

### BACKGROUND

Currently, tunnel oxide passivated solar cells (TOPCon) with higher photoelectric conversion efficiency are getting more market attention than conventional crystalline silicon cells. In the conventional technology, a tunnel passivated structure in the foregoing cell generally includes an ultra-thin tunnel oxide layer and a single phosphorus-doped polycrystalline silicon layer that are stacked, and the phosphorus-doped polycrystalline silicon layer is in contact with a metal electrode to transport electrons. However, the phosphorus-doped polycrystalline silicon layer causes a parasitic absorption effect, which affects photoelectric conversion efficiency of the TOPCon. In addition, a back surface of an existing TOPCon is passivated only by using a tunnel oxide passivated contact structure with a limited effect. Therefore, a solar cell with a new tunnel passivated contact structure needs to be provided to alleviate the foregoing problems.

### SUMMARY

This application provides a tunnel oxide passivated contact solar cell with a polycrystalline silicon-doped stack structure layer, where the tunnel oxide passivated contact solar cell has high photoelectric conversion efficiency.

According to a first aspect of this application, a tunnel oxide passivated contact solar cell is provided. The tunnel oxide passivated contact solar cell includes a first plurality of sequentially stacked layers, with the first plurality of sequentially stacked layers including a first anti-reflection layer, a passivation layer, an electrode emission layer, a silicon substrate layer, a tunnel oxide layer, a polycrystalline silicon-doped stack structure layer, and a second anti-reflection layer.

The polycrystalline silicon-doped stack structure layer includes a second plurality of sequentially stacked layers, with the second plurality of sequentially stacked layers including a first phosphorus-doped polycrystalline silicon layer, a phosphorus-carbon co-doped polycrystalline silicon layer, a second phosphorus-doped polycrystalline silicon layer, and a phosphorus-hydrogen co-doped polycrystalline silicon layer, and the first phosphorus-doped polycrystalline silicon layer is in contact with the tunnel oxide layer.

The first phosphorus-doped polycrystalline silicon layer and the tunnel oxide layer constitute a tunnel passivated structure. In addition, the phosphorus-carbon co-doped polycrystalline silicon layer can reduce an absorption rate and a parasitic absorption effect of the polycrystalline silicon stack layer on visible and infrared light, thereby improving photoelectric conversion efficiency of the cell while ensuring electron transport. Moreover, the phosphorus-carbon co-doped polycrystalline silicon layer has good electrical conductivity. Further, the second phosphorus-doped polycrystalline silicon layer between the phosphorus-carbon co-doped polycrystalline silicon layer and the phosphorus-hydrogen co-doped polycrystalline silicon layer can prevent mutual diffusion of doping elements in these two layers, thereby facilitating preparation of the cell and ensuring long-term stability of the cell. The phosphorus-hydrogen co-doped polycrystalline silicon layer has a passivation effect, and can improve photoelectric conversion efficiency of the cell. Therefore, the solar cell provided in the various embodiments of this application can have high photoelectric conversion efficiency, high stability, and a long service life.

In an embodiment of this application, a thickness of the polycrystalline silicon-doped stack structure layer ranges from 50 nm to 176 nm.

In an embodiment of this application, the thickness of the polycrystalline silicon-doped stack structure layer ranges from 78 nm to 114 nm.

In an embodiment of this application, a thickness of the first phosphorus-doped polycrystalline silicon layer ranges from 1.6 nm to 8 nm, a thickness of the phosphorus-carbon co-doped polycrystalline silicon layer ranges from 16 nm to 120 nm, a thickness of the second phosphorus-doped polycrystalline silicon layer ranges from 1.6 nm to 8 nm, and a thickness of the phosphorus-hydrogen co-doped polycrystalline silicon layer ranges from 4 nm to 40 nm.

In an embodiment of this application, the thickness of the first phosphorus-doped polycrystalline silicon layer ranges from 3.2 nm to 4.8 nm.

In an embodiment of this application, the thickness of the phosphorus-carbon co-doped polycrystalline silicon layer ranges from 56 nm to 72 nm.

In an embodiment of this application, the thickness of the second phosphorus-doped polycrystalline silicon layer ranges from 3.2 nm to 4.8 nm.

In an embodiment of this application, the thickness of the phosphorus-hydrogen co-doped polycrystalline silicon layer ranges from 16 nm to 32 nm.

In an embodiment of this application, the silicon substrate layer is an N-type silicon layer, the electrode emission layer is a boron-doped electrode emission layer, and a material of the tunnel oxide layer is selected from silicon oxide, titanium oxide, or aluminum oxide.

In an embodiment of this application, a thickness of the tunnel oxide layer is greater than 0 nm and less than or equal to 2 nm.

In an embodiment of this application, a thickness of the passivation layer ranges from 5 nm to 20 nm, a thickness of the first anti-reflection layer ranges from 10 nm to 120 nm, and a thickness of the second anti-reflection layer ranges from 10 nm to 120 nm.

According to a second aspect of this application, a photovoltaic module is provided, including the tunnel oxide passivated contact solar cell provided in the first aspect of this application.

In an embodiment of this application, the photovoltaic module further includes a front cover plate, a rear cover plate, a first encapsulant film, and a second encapsulant film. The front cover plate is bonded to a side of the tunnel oxide passivated contact solar cell by using the first encapsulant film, and the rear cover plate is bonded to another side of the tunnel oxide passivated contact solar cell by using the second encapsulant film.

With the tunnel oxide passivated contact solar cell of the present application, the photovoltaic module should have improved effectiveness and performance within the market.

### BRIEF DESCRIPTION OF DRAWINGS

To describe the technical solutions in the embodiments of this application more clearly, the following briefly describes the accompanying drawings. It should be appreciated that the accompanying drawings in the following descriptions merely show some embodiments of this application, and a person of ordinary skill in the art may still obtain other accompanying drawings from these accompanying drawings without creative efforts.

FIG. 1 is a schematic diagram of a cross-sectional structure of a structure of a tunnel oxide passivated contact solar cell according to an embodiment of this application; and

FIG. 2 is a schematic diagram of a structure of a photovoltaic module according to an embodiment of this application.

### DETAILED DESCRIPTION

The technical solutions in the embodiments of this application are clearly and wholly described below with reference to the accompanying drawings. It should be appreciated by those of ordinary skill in the art that the described embodiments are merely some, rather than all, of the embodiments of this application. All other embodiments obtained by a person of ordinary skill in the art based on the embodiments of this application without creative efforts shall fall within the protective scope of this application.

It should be understood that, in the descriptions of the embodiments of this application, the terms “first” and “second” are merely used for description purposes, and should not be understood as indicating or implying relative importance or implicitly indicating a quantity of technical features indicated. Therefore, features defined with “first” and “second” may explicitly or implicitly include one or more of the features. In the descriptions of the embodiments of this application, “a plurality of” means two or more, unless otherwise explicitly defined.

In the descriptions of the embodiments of this application, it should be noted that, unless otherwise specified or limited, terms “communicate” and “connect” should be understood in a broad sense, for example, may be a fixed connection, a detachable connection, or an integrated connection, may be a mechanical connection, an electrical connection, or mutual communication, may be a direct connection or an indirect connection implemented by using an intermediate medium, or may be communication between two elements or an interaction relationship between two elements. A person of ordinary skill in the art may understand specific meanings of the foregoing terms in the embodiments of this application based on specific situations.

The foregoing disclosure provides many different embodiments or examples for implementing different structures in the implementations of this application. To simplify the disclosure of the embodiments of this application, components and settings of specific examples are described herein. However, it should be appreciated that the components and the settings are merely examples and are not intended to limit this application. In addition, reference numerals and/or reference letters may be repeated in different examples in the embodiments of this application for simplicity and clarity purposes, and do not indicate a relationship between the various embodiments and/or settings discussed. In addition, the embodiments of this application provide examples of various specific processes and materials, but a person of ordinary skill in the art may be aware of application of other processes and/or use of other materials.

In this application, descriptions referring to the terms “one embodiment”, “some embodiments”, “examples”, “specific examples”, or “some examples” mean that specific features, structures, materials, or characteristics described with reference to this embodiment or example are included in at least one embodiment or example of this application. In this specification, illustrative expressions of the foregoing terms do not necessarily refer to the same embodiment or example. In addition, the described specific features, structures, materials, or characteristics may be combined in an appropriate manner in any one or more embodiments or examples.

In a tunnel oxide passivated contact solar cell (TOPCon), a tunnel passivated contact structure is provided on a back surface of the cell (a front surface of the solar cell is a surface facing sunlight, and a surface facing away from sunlight is the back surface). After sunlight illuminates the front surface of the solar cell, free electrons are generated in a silicon substrate layer (generally, an N-type silicon substrate layer). The free electrons tunnel through a tunnel oxide layer and enter a doped polycrystalline silicon layer (correspondingly and generally, a phosphorus-doped polycrystalline silicon layer), and the free electrons laterally diffuse and are collected by an electrode (generally, a metal electrode, particularly a silver electrode), enabling current transport. However, in an existing TOPCon, a parasitic effect of a phosphorus-doped polycrystalline silicon layer also reduces photoelectric conversion efficiency of the TOPCon. To resolve the foregoing problem, this application provides an improved solar cell.

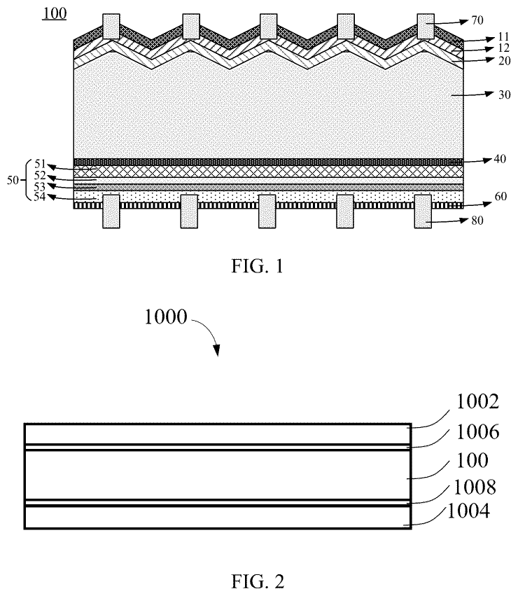

Referring to FIG. 1, an embodiment of this application provides a tunnel oxide passivated contact solar cell 100, including a first plurality of sequentially stacked layers, with the first plurality of sequentially stacked layers includes a first anti-reflection layer 11, a passivation layer 12, an electrode emission layer 20, a silicon substrate layer 30, a tunnel oxide layer 40, a polycrystalline silicon-doped stack structure layer 50, and a second anti-reflection layer.

The polycrystalline silicon-doped stack structure layer 50, itself, includes a second plurality of sequentially stacked layers, with the second plurality of sequentially stacked layers forming a part of the first plurality of sequentially stacked layers and including a first phosphorus-doped polycrystalline silicon layer 51, a phosphorus-carbon co-doped polycrystalline silicon layer 52, a second phosphorus-doped polycrystalline silicon layer 53, and a phosphorus-hydrogen co-doped polycrystalline silicon layer 54. The first phosphorus-doped polycrystalline silicon layer 51 is in contact with the tunnel oxide layer 40. That is, the first phosphorus-doped polycrystalline silicon layer 51 is located on a surface of the tunnel oxide layer 40 that faces away from the silicon substrate layer 30. Electrons reach the phosphorus-hydrogen co-doped polycrystalline silicon layer 54 after sequentially passing through the tunnel oxide layer 40, the first phosphorus-doped polycrystalline silicon layer 51, the phosphorus-carbon co-doped polycrystalline silicon layer 52, and the second phosphorus-doped polycrystalline silicon layer 53, and laterally diffuse in the phosphorus-hydrogen co-doped polycrystalline silicon layer 54 to be collected by an electrode, thereby completing photovoltaic conversion.

After sunlight illuminates a front surface of the solar cell, free electrons generated in the silicon substrate layer 30 move into the first phosphorus-doped polycrystalline silicon layer 51 through the tunnel oxide layer 40. The first phosphorus-doped polycrystalline silicon layer 51 and the tunnel oxide layer 40 are common tunnel passivated structures in the art. The first phosphorus-doped polycrystalline silicon layer 51 can further induce band bending on a surface of a silicon wafer, thereby significantly increasing a probability of electron tunneling. In addition, the phosphorus-carbon co-doped polycrystalline silicon layer 52 can reduce an absorption rate and a parasitic absorption effect of the polycrystalline silicon-doped stack structure layer 50 on visible and infrared light, thereby improving photoelectric conversion efficiency of the cell while ensuring electron transport. In addition, the phosphorus-carbon co-doped polycrystalline silicon layer 52 has low resistivity, which can improve electronic conductivity of the polycrystalline silicon-doped stack structure layer 50. Further, the second phosphorus-doped polycrystalline silicon layer 53 between the phosphorus-carbon co-doped polycrystalline silicon layer 52 and the phosphorus-hydrogen co-doped polycrystalline silicon layer 54 can prevent mutual diffusion of doping elements in the phosphorus-carbon co-doped polycrystalline silicon layer 52 and the phosphorus-hydrogen co-doped polycrystalline silicon layer 54 (for example, element diffusion in a preparation process of the cell), thereby preventing the elements in these two layers from affecting each other. Hydrogen atoms in the phosphorus-hydrogen co-doped polycrystalline silicon layer 54 can saturate dangling bonds on surfaces of silicon atoms, so that this layer has a passivation effect. Therefore, a passivation effect on an interface between the polycrystalline silicon-doped stack structure layer 50 and the second anti-reflection layer 60 can be improved, thereby passivating surface defects in polycrystalline silicon, reducing recombination of photogenerated electrons, and further improving photoelectric conversion efficiency of the cell.

It may be understood that, to collect electrons to form a current, electrodes (grid lines) are provided on both the front surface and a back surface of the solar cell. In some embodiments of this application, a first electrode 70 and a second electrode 80 are respectively provided on the first anti-reflection layer 11 and the second anti-reflection layer 60. The second electrode 80 is in contact with at least the phosphorus-hydrogen co-doped polycrystalline silicon layer 54. In a specific embodiment of this application, the provision of the first electrode 70 on the first anti-reflection layer 11 includes, but is not limited to, the following case: the first electrode 70 may be located on a surface of the first anti-reflection layer 11, or the first electrode 70 runs through/is partially embedded into but does not run through the first anti-reflection layer 11 and protrudes relative to the first anti-reflection layer 11. Further, the first electrode 70 may further extend into the passivation layer 12. In this application, the indication that the second electrode 80 is in contact with at least the phosphorus-hydrogen co-doped polycrystalline silicon layer 54 may mean that the second electrode 80 runs through the second anti-reflection layer 60 and is in contact with the phosphorus-hydrogen co-doped polycrystalline silicon layer 54, but is not limited thereto. In some specific embodiments, the second electrode 80 may alternatively extend in a direction from the phosphorus-hydrogen co-doped polycrystalline silicon layer 54 to the first phosphorus-doped polycrystalline silicon layer 51 without running through the first phosphorus-doped polycrystalline silicon layer 51. According to one aspect, in some specific embodiments of this application, an end of the second electrode 80 that is away from the phosphorus-hydrogen co-doped polycrystalline silicon layer 54 protrudes relative to the second anti-reflection layer 60. However, the present application his is not limited to this configuration of the second electrode 80.

Generally, in a process of using the solar cell, a side of the first anti-reflection layer 11 is the front surface of the solar cell (facing sunlight), and a side on which a tunnel oxide passivated contact structure is provided is the back surface of the solar cell. Therefore, the first anti-reflection layer 11 is also referred to as a “front anti-reflection layer”, and the second anti-reflection layer 60 is also referred to as a “back anti-reflection layer”.

In an embodiment of this application, the silicon substrate layer 30 is an N-type silicon layer. The electrode emission layer 20 is a boron-doped electrode emission layer. In some embodiments of this application, a material of the tunnel oxide layer 40 includes, but is not limited to, at least one of silicon oxide, titanium oxide, or aluminum oxide. In some embodiments of this application, a material of the passivation layer 12 includes, but is not limited to, at least one of silicon oxide, silicon oxynitride, or aluminum oxide. Materials of the first anti-reflection layer 11 and the second anti-reflection layer 60 are separately selected from at least one of silicon oxide, silicon nitride, or silicon oxynitride. In some specific embodiments, the passivation layer 12 is an aluminum oxide layer, and both the first anti-reflection layer 11 and the second anti-reflection layer 60 are silicon nitride layers. In some specific embodiments, a refractive index of the first anti-reflection layer 11 is different from a refractive index of the second anti-reflection layer 60. Materials of the first electrode 70 and the second electrode 80 are separately selected from metal materials, such as silver and aluminum, but are not limited thereto.

It should be noted that, in FIG. 1 of this application, the first anti-reflection layer 11, the passivation layer 12, and the electrode emission layer 20 are in a wavy shape, to conform to a pyramidal light-trapping structure formed on a side surface (the front surface) of the silicon substrate layer through a texturing process. The wavy shape is a common illustration pattern in the art, and sets no limitation on forms of the first anti-reflection layer 11, the passivation layer 12, and the electrode emission layer 20 in this application.

In some embodiments of this application, a doping concentration of phosphorus atoms in the first phosphorus-doped polycrystalline silicon layer 51 ranges from 1×10¹⁹ cm⁻³ to 9×10²¹ cm⁻³. In this way, the probability of electron tunneling can be better increased, and resistivity of the first phosphorus-doped polycrystalline silicon layer 51 can be reduced. For example, the doping concentration of the phosphorus atoms in the first phosphorus-doped polycrystalline silicon layer 51 may be, but is not limited to, 1×10¹⁹ cm⁻³, 2×10¹⁹ cm⁻³, 3×10¹⁹ cm⁻³, 4×10¹⁹ cm⁻³, 5×10¹⁹ cm⁻³, 6×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 8×10²⁰ cm⁻³, 9×10²⁰ cm⁻³, 1×10²¹ cm⁻³, 2×10²¹ cm⁻³, 5×10²¹ cm⁻³, 8×10²¹ cm⁻³, or 9×10²¹ cm⁻³.

In some embodiments of this application, in the phosphorus-carbon co-doped polycrystalline silicon layer 52, a doping concentration of phosphorus atoms ranges from 1×10¹⁹ cm⁻³ to 9×10²¹ cm⁻³, and a doping concentration of carbon atoms ranges from 1×10¹⁷ cm⁻³ to 5×10²¹ cm⁻³. The doping concentrations of the phosphorus atoms and the carbon atoms in the phosphorus-carbon co-doped polycrystalline silicon layer 52 are controlled within the foregoing ranges, to more effectively reduce the parasitic absorption effect of the polycrystalline silicon-doped stack structure layer 50 and fully reduce resistivity, thereby further improving photoelectric conversion efficiency of the solar cell. For example, the doping concentration of the phosphorus atoms in the phosphorus-carbon co-doped polycrystalline silicon layer 52 may be, but is not limited to, 1×10¹⁹ cm⁻³, 2×10¹⁹ cm⁻³, 3×10¹⁹ cm⁻³, 4×10¹⁹ cm⁻³, 6×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 8×10²⁰ cm⁻³, 9×10²⁰ cm⁻³, 1×10²¹ cm⁻³, 2×10²¹ cm⁻³, 5×10²¹ cm⁻³, 8×10²¹ cm⁻³, or 9×10²¹ cm⁻³. For example, the doping concentration of the carbon atoms in the phosphorus-carbon co-doped polycrystalline silicon layer 52 may be, but is not limited to, 1×10¹⁷ cm⁻³, 5×10¹⁷ cm⁻³, 8×10¹⁷ cm⁻³, 1×10¹⁸ cm⁻³, 5×10¹⁸ cm⁻³, 8×10¹⁸ cm⁻³, 1×10¹⁹ cm⁻³, 5×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 6×10²⁰ cm⁻³, 7×10²⁰ cm⁻³, 8×10²⁰ cm⁻³, 9×10²⁰ cm⁻³, 1×10²¹ cm⁻³, 2×10²¹ cm⁻³, 3×10²¹ cm⁻³, or 4×10²¹ cm⁻³.

In some embodiments of this application, a doping concentration of phosphorus atoms in the second phosphorus-doped polycrystalline silicon layer 53 (phosphorus-doped polycrystalline silicon layer) ranges from 1×10¹⁹ cm⁻³ to 9×10²¹ cm⁻³. In this way, it is possible both to achieve isolation of doping atoms and prevent layer intermixing, and to facilitate performance exertion of the solar cell. For example, the doping concentration of the phosphorus atoms in the second phosphorus-doped polycrystalline silicon layer 53 may be, but is not limited to, 1×10¹⁹ cm⁻³, 2×10¹⁹ cm⁻³, 3×10¹⁹ cm⁻³, 4×10¹⁹ cm⁻³, 6×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 8×10²⁰ cm⁻³, 9×10²⁰ cm⁻³, 1×10²¹ cm⁻³, 2×10²¹ cm⁻³, 5×10²¹ cm⁻³, 8×10²¹ cm⁻³, or 9×10²¹ cm⁻³. In this embodiment of this application, the doping concentration of the phosphorus atoms in the second phosphorus-doped polycrystalline silicon layer 53 may be the same as or different from that of the first phosphorus-doped polycrystalline silicon layer 51.

In some embodiments of this application, in the phosphorus-hydrogen co-doped polycrystalline silicon layer 54, a doping concentration of phosphorus atoms ranges from 1×10¹⁹ cm⁻³ to 9×10²¹ cm⁻³, and a doping concentration of hydrogen atoms ranges from 1×10¹⁷ cm⁻³ to 5×10²¹ cm⁻³. Content of the phosphorus atoms and content of the hydrogen atoms are controlled within the foregoing ranges, so that the phosphorus-hydrogen co-doped polycrystalline silicon layer 54 has a better passivation effect and good electronic conductivity. For example, the doping concentration of the phosphorus atoms in the phosphorus-hydrogen co-doped polycrystalline silicon layer 54 may be, but is not limited to, 1×10¹⁹ cm⁻³, 2×10¹⁹ cm⁻³, 3×10¹⁹ cm⁻³, 4×10¹⁹ cm⁻³, 6×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 6×10²⁰ cm⁻³, 7×10²⁰ cm⁻³, 8×10²⁰ cm⁻³, 9×10²⁰ cm⁻³, 1×10²¹ cm⁻³, 2×10²¹ cm⁻³, 5×10²¹ cm⁻³, 8×10²¹ cm⁻³, or 9×10²¹ cm⁻³. For example, the doping concentration of the hydrogen atoms in the phosphorus-hydrogen co-doped polycrystalline silicon layer 54 may be, but is not limited to, 1×10¹⁷ cm⁻³, 5×10¹⁷ cm⁻³, 8×10¹⁷ cm⁻³, 1×10¹⁸ cm⁻³, 5×10¹⁸ cm⁻³, 8×10¹⁸ cm⁻³, 1×10¹⁹ cm⁻³, 5×10¹⁹ cm⁻³, 8×10¹⁹ cm⁻³, 1×10²⁰ cm⁻³, 2×10²⁰ cm⁻³, 3×10²⁰ cm⁻³, 4×10²⁰ cm⁻³, 5×10²⁰ cm⁻³, 6×10²⁰ cm⁻³, 7×10²⁰ cm⁻³, 8×10²⁰ cm⁻³, 9×10²⁰ cm⁻³, 1×10²¹ cm⁻³, 2×10²¹ cm⁻³, or 5×10²¹ cm⁻³.

In some embodiments of this application, a thickness of the first phosphorus-doped polycrystalline silicon layer 51 ranges from 1.6 nm to 8.0 nm. For example, the thickness of the first phosphorus-doped polycrystalline silicon layer 51 may be, but is not limited to, 1.6 nm, 2 nm, 3 nm, 3.5 nm, 4 nm, 4.2 nm, 4.5 nm, 5 nm, 5.5 nm, 6 nm, 7 nm, or 8 nm. In some specific embodiments, the thickness of the first phosphorus-doped polycrystalline silicon layer 51 ranges from 3.2 nm to 4.8 nm. The thickness of the first phosphorus-doped polycrystalline silicon layer 51 is controlled within the foregoing range, thereby facilitating electron tunneling, and further reducing the parasitic absorption effect.

In some embodiments of this application, a thickness of the phosphorus-carbon co-doped polycrystalline silicon layer 52 ranges from 16 nm to 120 nm. In some specific embodiments, the thickness of the phosphorus-carbon co-doped polycrystalline silicon layer 52 ranges from 56 nm to 72 nm. For example, the thickness of the phosphorus-carbon co-doped polycrystalline silicon layer 52 may be, but is not limited to, 16 nm, 20 nm, 30 nm, 40 nm, 50 nm, 55 nm, 56 nm, 60 nm, 65 nm, 70 nm, 80 nm, 90 nm, 100 nm, 110 nm, or 120 nm. The thickness of the phosphorus-carbon co-doped polycrystalline silicon layer 52 is controlled within the foregoing range, to further ensure that the parasitic absorption effect of the cell is weak, thereby ensuring high photoelectric conversion efficiency of the cell.

In some embodiments of this application, a thickness of the second phosphorus-doped polycrystalline silicon layer 53 ranges from 1.6 nm to 8.0 nm. For example, the thickness of the second phosphorus-doped polycrystalline silicon layer 53 may be, but is not limited to, 1.6 nm, 2 nm, 3 nm, 4 nm, 5 nm, 6 nm, 7 nm, or 8 nm. In some specific embodiments, the thickness of the second phosphorus-doped polycrystalline silicon layer 53 ranges from 3.2 nm to 4.8 nm. The thickness of the second phosphorus-doped polycrystalline silicon layer 53 is controlled within the foregoing range, to implement a good isolation effect, ensure that the overall parasitic absorption effect of the polycrystalline silicon-doped stack structure layer 50 is weak, and further help control an overall thickness of the solar cell to be small. In this embodiment of this application, the thickness of the second phosphorus-doped polycrystalline silicon layer 53 may be the same as or different from the thickness of the first phosphorus-doped polycrystalline silicon layer 51.

In some embodiments of this application, a thickness of the phosphorus-hydrogen co-doped polycrystalline silicon layer 54 ranges from 4 nm to 40 nm. For example, the thickness of the phosphorus-hydrogen co-doped polycrystalline silicon layer 54 may be, but is not limited to, 5 nm, 10 nm, 15 nm, 20 nm, 25 nm, 28 nm, 30 nm, 32 nm, 35 nm, or 40 nm. In some specific embodiments, the thickness of the phosphorus-hydrogen co-doped polycrystalline silicon layer 54 may range from 16 nm to 32 nm. In this way, a total thickness of the solar cell can be controlled to be small, and a passivation effect of the cell can be improved better.

In some embodiments of this application, a thickness of the polycrystalline silicon-doped stack structure layer 50 ranges from 50 nm to 176 nm. In some specific embodiments, the thickness of the polycrystalline silicon-doped stack structure layer 50 ranges from 78 nm to 114 nm. For example, the thickness of the polycrystalline silicon-doped stack structure layer 50 may be, but is not limited to, 50 nm, 55 nm, 60 nm, 65 nm, 70 nm, 75 nm, 78 nm, 80 nm, 82 nm, 85 nm, 90 nm, 92 nm, 95 nm, 98 nm, 100 nm, 105 nm, 110 nm, 112 nm, 114 nm, 118 nm, 120 nm, 130 nm, 140 nm, 150 nm, 160 nm, 170 nm, or 175 nm.

In some embodiments of this application, a thickness of the tunnel oxide layer 40 is greater than 0 nm and less than or equal to 2 nm.

In some embodiments of this application, a thickness of the passivation layer 12 ranges from 5 nm to 20 nm, and thicknesses of the first anti-reflection layer 11 and the second anti-reflection layer 60 separately range from 10 nm to 120 nm. The thicknesses of the first anti-reflection layer 11, the passivation layer 12, and the second anti-reflection layer 60 are controlled within the foregoing ranges to ensure performance exertion of the cell and control the total thickness of the solar cell to be small. For example, the thickness of the passivation layer 12 may be, but is not limited to, 5 nm, 8 nm, 10 nm, 12 nm, 15 nm, or 18 nm. For example, the thicknesses of the first anti-reflection layer 11 and the second anti-reflection layer 60 may be separately, but are not limited to, 10 nm, 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, or 115 nm.

In a specific embodiment of this application, the tunnel oxide passivated contact solar cell includes a first anti-reflection layer 11 (specifically, a silicon nitride layer with a thickness of 80 nm), a passivation layer 12 (specifically, an aluminum oxide layer with a thickness of 12 nm), an electrode emission layer 20, a silicon substrate layer 30 (specifically, an N-type silicon substrate layer with a thickness of 130 μm), a tunnel oxide layer 40 (specifically, a silicon oxide layer with a thickness of 1.6 nm), a polycrystalline silicon-doped stack structure layer 50, and a second anti-reflection layer 60 (specifically, a silicon nitride layer with a thickness of 80 nm), with such various layers being sequentially stacked. The polycrystalline silicon-doped stack structure includes a first phosphorus-doped polycrystalline silicon layer 51 (with a thickness of 5 nm), a phosphorus-carbon co-doped polycrystalline silicon layer 52 (with a thickness of 80 nm), a second phosphorus-doped polycrystalline silicon layer 53 (with a thickness of 5 nm), and a phosphorus-hydrogen co-doped polycrystalline silicon layer 54 (with a thickness of 12 nm), with such layers being sequentially stacked. Further, a first electrode 70 and a second electrode 80 are respectively provided on the first anti-reflection layer 11 and the second anti-reflection layer 60.

In some embodiments of this application, preparation of the tunnel oxide passivated contact solar cell includes the following steps:
S01: Preprocess a silicon wafer raw material.
S02: Form an electrode emission layer on a side surface (a front surface) of the silicon wafer, and polish a back surface of the silicon wafer, to obtain the electrode emission layer and a silicon substrate layer.
S03: Deposit a tunnel oxide layer on the back surface of the silicon wafer by using a thermal oxidation process, a thermal nitric acid oxidation process, an ozone oxidation process, or a plasma-assisted nitrous oxide process.
S04: Prepare a polycrystalline silicon-doped stack structure layer on a surface of the tunnel oxide layer.
S05: Prepare a passivation layer on a surface of the electrode emission layer.
S06: Prepare a first anti-reflection layer on a surface of the passivation layer, and provide a second anti-reflection layer on a surface of the polycrystalline silicon-doped stack structure that faces away from the tunnel oxide layer.
S07: Prepare a first electrode and a second electrode. An electrode paste is separately printed on surfaces of the first anti-reflection layer and the second anti-reflection layer, and then high-temperature sintering is performed, to obtain the first electrode and the second electrode. In some specific embodiments, the foregoing printing is screen printing.

In some embodiments of this application, in S07, the electrode paste is printed on the surface of the second anti-reflection layer, so that the paste burns through the second anti-reflection layer, and high-temperature sintering is performed to obtain the second electrode. The second electrode is in contact with the polycrystalline silicon-doped stack structure layer to better collect electrons. Specifically, the second electrode is in contact with at least a phosphorus-hydrogen co-doped polycrystalline silicon layer in the polycrystalline silicon-doped stack structure layer to collect electrons. Further, the second electrode may extend in a direction facing away from the second anti-reflection layer to reach any position in the polycrystalline silicon-doped stack structure layer, and may even be sequentially in contact with a second phosphorus-doped polycrystalline silicon layer, a phosphorus-carbon co-doped polycrystalline silicon layer, and a first phosphorus-doped polycrystalline silicon layer without running through the polycrystalline silicon-doped stack structure layer and being in contact with the tunnel oxide layer.

An embodiment of this application further provides a photovoltaic module 1000, including the solar cell provided in the embodiments of this application. Referring to FIG. 2, the photovoltaic module 1000 further includes a front cover plate 1002, a rear cover plate 1004, a first encapsulant film 1006, and a second encapsulant film 1008. The front cover plate 1002 is bonded to a side of the tunnel oxide passivated contact solar cell 100 by using the first encapsulant film 1006. The rear cover plate 1004 is bonded to another side (e.g., an opposed side) of the tunnel oxide passivated contact solar cell 100 by using the second encapsulant film 1008.

With the solar cell provided in this application, the photovoltaic module 1000 has high market competitiveness.

The foregoing descriptions are merely example embodiments of this application. It should be noted that a person of ordinary skill in the art can further make several improvements and modifications to this application without departing from the principles of this application, and the improvements and modifications fall within the protective scope of this application.

Reference Number Description: 100—solar cell; 11—first anti-reflection layer; 12—passivation layer; 20—electrode emission layer; 30—silicon substrate layer; 40—tunnel oxide layer; 50—polycrystalline silicon-doped stack structure layer; 51—first phosphorus-doped polycrystalline silicon layer; 52—phosphorus-carbon co-doped polycrystalline silicon layer; 53—second phosphorus-doped polycrystalline silicon layer; 54—phosphorus-hydrogen co-doped polycrystalline silicon layer; 60—second anti-reflection layer; 70—first electrode; 80—second electrode; 1000—photovoltaic module; 1002—front cover plate; 1004—rear cover plate; 1006—first encapsulant film; and 1008—second encapsulant film.

1. A tunnel oxide passivated contact solar cell, comprising:
a first plurality of sequentially stacked layers, the first plurality of sequentially stacked layers including a first anti-reflection layer, a passivation layer, an electrode emission layer, a silicon substrate layer, a tunnel oxide layer, a polycrystalline silicon-doped stack structure layer, and a second anti-reflection layer,
wherein:
the polycrystalline silicon-doped stack structure layer comprises a second plurality of sequentially stacked layers, the second plurality of sequentially stacked layers including a first phosphorus-doped polycrystalline silicon layer, a phosphorus-carbon co-doped polycrystalline silicon layer, a second phosphorus-doped polycrystalline silicon layer, and a phosphorus-hydrogen co-doped polycrystalline silicon layer, and
the first phosphorus-doped polycrystalline silicon layer is in contact with the tunnel oxide layer.

2. The tunnel oxide passivated contact solar cell according to claim 1, wherein a thickness of the polycrystalline silicon-doped stack structure layer ranges from 50 nm to 176 nm.

3. The tunnel oxide passivated contact solar cell (100) according to claim 1, wherein a thickness of the polycrystalline silicon-doped stack structure layer ranges from 78 nm to 114 nm.

4. The tunnel oxide passivated contact solar cell according to claim 1, wherein a thickness of the first phosphorus-doped polycrystalline silicon layer ranges from 1.6 nm to 8 nm, a thickness of the phosphorus-carbon co-doped polycrystalline silicon layer ranges from 16 nm to 120 nm, a thickness of the second phosphorus-doped polycrystalline silicon layer ranges from 1.6 nm to 8 nm, and a thickness of the phosphorus-hydrogen co-doped polycrystalline silicon layer ranges from 4 nm to 40 nm.

5. The tunnel oxide passivated contact solar cell according to claim 1, wherein a thickness of the first phosphorus-doped polycrystalline silicon layer ranges from 3.2 nm to 4.8 nm.

6. The tunnel oxide passivated contact solar cell according to claim 1, wherein a thickness of the phosphorus-carbon co-doped polycrystalline silicon layer ranges from 56 nm to 72 nm.

7. The tunnel oxide passivated contact solar cell according to claim 1, wherein a thickness of the second phosphorus-doped polycrystalline silicon layer ranges from 3.2 nm to 4.8 nm.

8. The tunnel oxide passivated contact solar cell according to claim 1, wherein a thickness of the phosphorus-hydrogen co-doped polycrystalline silicon layer ranges from 16 nm to 32 nm.

9. The tunnel oxide passivated contact solar cell according to claim 1, wherein the silicon substrate layer is an N-type silicon layer, the electrode emission layer is a boron-doped electrode emission layer, and a material of the tunnel oxide layer is selected from silicon oxide, titanium oxide, or aluminum oxide.

10. The tunnel oxide passivated contact solar cell according to claim 1, wherein a thickness of the tunnel oxide layer is greater than 0 nm and less than or equal to 2 nm.

11. The tunnel oxide passivated contact solar cell according to claim 1, wherein a thickness of the passivation layer ranges from 5 nm to 20 nm, a thickness of the first anti-reflection layer ranges from 10 nm to 120 nm, and a thickness of the second anti-reflection layer ranges from 10 nm to 120 nm.

12. A photovoltaic module, wherein the photovoltaic module comprises the tunnel oxide passivated contact solar cell according to claim 1.

13. The photovoltaic module according to claim 12, wherein the photovoltaic module further comprises a front cover plate, a rear cover plate, a first encapsulant film, and a second encapsulant film, and wherein the front cover plate is bonded to a side of the tunnel oxide passivated contact solar cell by using the first encapsulant film, and the rear cover plate is bonded to another side of the tunnel oxide passivated contact solar cell by using the second encapsulant film.
